(19) United States
(12) Patent Application Publication
(10) Pub. No.: US 2018/0061887 A1
(43) Pub. Date: Mar. 1, 2018

(54) MAGNETORESISTIVE RANDOM ACCESS MEMORY (MRAM) WITH AN INTERCONNECT THAT GENERATES A SPIN CURRENT AND A MAGNETIC FIELD EFFECT

(71) Applicant: HGST Netherlands B.V., Amsterdam (NL)

(72) Inventor: Patrick Mesquita Braganca, San Jose, CA (US)

(21) Appl. No.: 15/247,293

(22) Filed: Aug. 25, 2016

(51) Int. Cl. H01L 27/22; H01L 43/08; H01L 43/04; G11C 11/16; H01L 43/10; H01L 23/528

(52) U.S. Cl. CPC H01L 27/228; H01L 43/08; H01L 23/528; G11C 11/161; H01L 43/10; H01L 43/04

(57) ABSTRACT

An MRAM cell having an MTJ stack with a free layer and an interconnect configured to generate a spin current and a magnetic field effect that is used to affect the magnetic moment of the free layer. The interconnect may comprise a Spin Hall lead. The interconnect may comprise an antiferromagnetic material. An MRAM cell array may include a plurality of bit elements each configured to store at least one bit, an interconnect coupled to the plurality of bit elements, and a transistor formed at a periphery of the MRAM cell array and configured to supply a current to the plurality of bit elements via the interconnect. The interconnect may be configured to generate a spin current and a magnetic field effect that is used to affect the magnetic moment of the free layer of each of the plurality of bit elements.

### BACKGROUND

### Field

Aspects of the present disclosure relate generally to magnetoresistive random access memory (MRAM), and more particularly, to perpendicular magnetic anisotropy (PMA) magnetic tunnel junctions (MTJ).

### Description of Related Art

One class of solid state memory devices, or nonvolatile memory, is Magnetic Random Access Memory (MRAM). MRAM devices comprise cells or elements having a magnetically hard layer, e.g., a reference layer (also referred to as a “pinned” or “fixed” layer) and a magnetically soft layer, e.g., a free layer as parts of a magnetic tunnel junction (MTJ). The magnetization of the reference layer is pinned or fixed. However, a switching current through the MTJ causes the magnetization of the free layer to switch between the two orientations, e.g. parallel or antiparallel to the reference layer magnetization orientation. The tunneling magnetoresistance (TMR) of the MTJ changes based on whether the free layer magnetization is parallel or antiparallel to that of the reference layer. The two different resistance states of the MTJ may indicate a “0” or “1” stored in the MRAM.

Writing to MRAM can be performed by passing current through current leads that are formed on either side of each memory element in order to create a local induced magnetic field which sets the direction of the free layer magnetization. Significant problems have been encountered however in scaling these devices to high densities. In particular, disturbances to neighboring cells or elements can occur during writing, sometimes causing a neighboring cell to be erroneously written.

Spin Transfer Torque (STT) MRAM is a nonvolatile memory technology that is fast, low power, and high endurance. STT devices are similar to MRAM devices except that the current paths pass through the magnetic layers of each memory element, rather than to the side of each memory element, and the free layer of the memory element can be set via the transfer of spin torque from the spin polarized current passing through that layer. This approach can require high current densities, which are undesirable due to heat and power consumption concerns. In addition, this approach leads to challenges with scaling to high densities.

Endurance issues arise in STT MRAM because currents may be repeatedly passed through the MTJ bit elements by placing a voltage bias across the oxide tunnel barrier of the MTJ. Constant cycling of this current eventually breaks down the oxide tunnel barrier and leads to bit failure.

One alternative to conventional STT switching is to use the spin hall effect. In the spin hall effect, current passing through a nonmagnetic conductor can generate a spin current that can then interact with a ferromagnet adjacent to the nonmagnetic conductor. In this manner, MTJ bits could be written without passing any current across the tunnel barriers, effectively leading to infinite endurance for MRAM. Spin hall switching with perpendicular magnetic anisotropy (PMA) layers is more desirable than in-plane magnetized MTJs for memory, because PMA allows for higher data storage density

While spin hall switching works quite well for ferromagnets with magnetic moments in the plane of the film, switching ferromagnets with magnetic moments out of the film plane, e.g., for PMA layers is difficult. Switching PMA MTJs requires both a current through the spin hall material and a magnetic field bias along the direction of current flow in order to reliably switch the PMA MTJ between different states.

### SUMMARY

Aspects presented herein are directed to enabling PMA MTJ bits to be switched using the spin hall effect without requiring the generation of an external magnetic field.

In an aspect of the disclosure, a MRAM cell is provided, the MRAM cell comprises an MTJ stack having a free layer. The MRAM cell also comprises an interconnect configured to generate a spin current and a magnetic field effect in the MTJ stack that is used to affect the magnetic moment of the free layer. The interconnect may comprise a Spin Hall lead, for example. The interconnect may comprise an antiferromagnetic material.

In another aspect, an MRAM cell array is provided with a plurality of bit elements each configured to store at least one bit. An interconnect may be coupled to the plurality of bit elements, and at least one transistor may be formed at a periphery of the MRAM cell array and configured to supply a current to the plurality of bit elements via the first interconnect. The interconnect may be configured to generate a spin current and a magnetic field effect that is used to affect the magnetic moment of the free layer of each of the plurality of bit elements. The interconnect may comprise a Spin Hall lead. The interconnect may comprise an antiferromagnetic material.

In another aspect, an MRAM cell is provided, the MRAM cell comprising an MTJ stack having a free layer and an antiferromagnetic material exchange coupled to the free layer and configured to generate a spin current. The antiferromagnetic material may comprise a Spin Hall lead.

In another aspect, an MRAM cell is provided, the MRAM cell comprising an MTJ stack having free layer with perpendicular magnetic anisotropy and a tunnel barrier deposited directly on a side of the free layer and an interconnect positioned on an opposite side of the free layer and configured to generate a spin current. The interconnect may comprise a Spin Hall lead.

It will be understood that other aspects of MRAM cells and MRAM cell arrays will become readily apparent to those skilled in the art from the following detailed description, wherein it is shown and described only several embodiments of the invention by way of illustration. As will be realized by those skilled in the art, the present invention is capable of other and different embodiments and its several details are capable of modification in various other respects, all without departing from the spirit and scope of the invention. Accordingly, the drawings and detailed description are to be regarded as illustrative in nature and not as restrictive.

### BRIEF DESCRIPTION OF THE DRAWINGS

Various example aspects of the systems and methods will be described in detail, with reference to the following figures, wherein:

FIGS. 1A and 1B illustrate aspects of two possible states of an example PMA MTJ memory cell, in accordance with aspects of the present disclosure.

FIG. 2 illustrates an example of MRAM cell array having an array of MTJ memory cells connected to work and bits lines in a cross-point architecture, in accordance with aspects of the present disclosure.

FIG. 3 illustrates an example MRAM cell having an MTJ stack and interconnect, in accordance with aspects of the present disclosure.

FIG. 4 illustrates an example of MRAM cell array having an array of MTJ memory cells, in accordance with aspects of the present disclosure.

### DETAILED DESCRIPTION

The detailed description set forth below in connection with the appended drawings is intended as a description of various configurations and is not intended to represent the only configurations in which the concepts described herein may be practiced. The phrase “example aspects” used throughout this disclosure means “serving as an example, instance, or illustration,” and should not necessarily be construed as preferred or advantageous over other example aspects presented in this disclosure. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Various aspects of MRAM cells may be described with reference to certain shapes and geometries (e.g., regions, layers, sections, etc.), but the teachings herein extend to deviations in shapes that result, for example, from manufacturing. By way of example, a layer illustrated or described as a rectangle may have rounded or curved features and/or a gradient concentration at its edges rather than a discrete change from one level to another. Thus, regions, layers, sections and the like are illustrated in the drawings are schematic in nature and are not intended to limit the scope of the disclosure. Any reference to a region, layer, section, or the like having a particular shape or geometry, however, should not be construed as limited to the precise shape illustrated or described, but shall to include deviations that result, for example, from manufacturing techniques and/or tolerances.

It will be understood that when a region, layer, section, or the like, of an MRAM cell is referred to as being “between” other regions, layers, sections, or the like, it can be directly between such regions, layers, sections, or the like, or intervening elements may be present.

Several example aspects will now be presented in the context of STT MRAM cells and arrays. While these aspects may be well suited for these applications, those skilled in the art will realize that such aspects may be extended to other applications. Accordingly, any reference to a STT MRAM is intended only to illustrate various aspects, with the understanding that such aspects may have a wide range of applications.

STT MRAM with MTJ memory cells having PMA is a strong candidate for future non-volatile memory. The MTJ memory cell may have a free ferromagnetic layer (also called the recording layer or storage layer) and a reference ferromagnetic layer separated by a thin insulating tunnel barrier. The tunnel barrier is an oxide tunnel barrier material, such as MgO. The free and reference layers may be PMA layers with magnetizations oriented perpendicular to the planes of the layers. While the magnetization of the reference layer is pinned, a switching current through the MTJ causes the magnetization of the free layer to switch between the two orientations, e.g., parallel (P) or antiparallel (AP) to the reference layer magnetization. The TMR of the MTJ changes according to the orientation of the free layer so that the MTJ has resistance R_{P} or resistance R_{AP} depending on whether the orientation is P or AP.

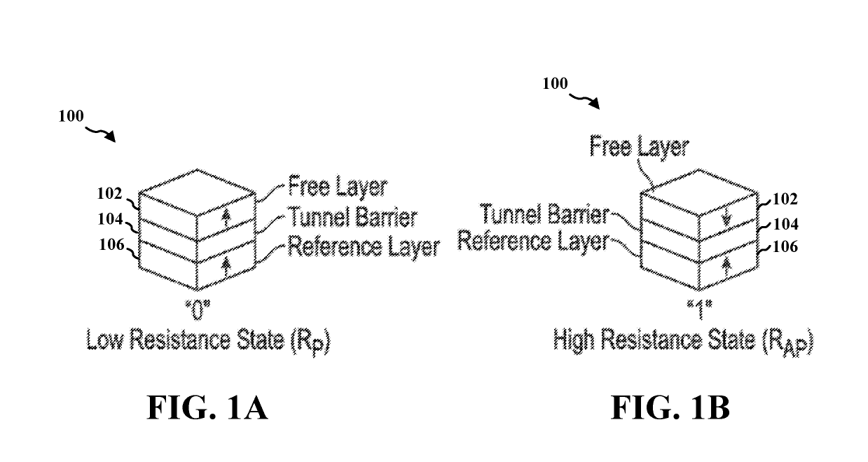

FIGS. 1A, 1B show two possible states of the MTJ. FIG. 1A shows an example when the free layer 102 has a magnetization that is parallel to the reference layer's 104 magnetization state. This state of the cell may provide a low resistance state, e.g., which may be designated a “0” stored in the memory. In FIG. 1A, the TMR of the MTJ is R_{P} corresponding to a parallel orientation. FIG. 1B shows an example when the free layer 304 has a magnetization that is antiparallel to the reference layer's magnetization state. This state of the cell may provide a higher resistance state, with TMR of R_{AP} and may designate a “1” stored in the memory.

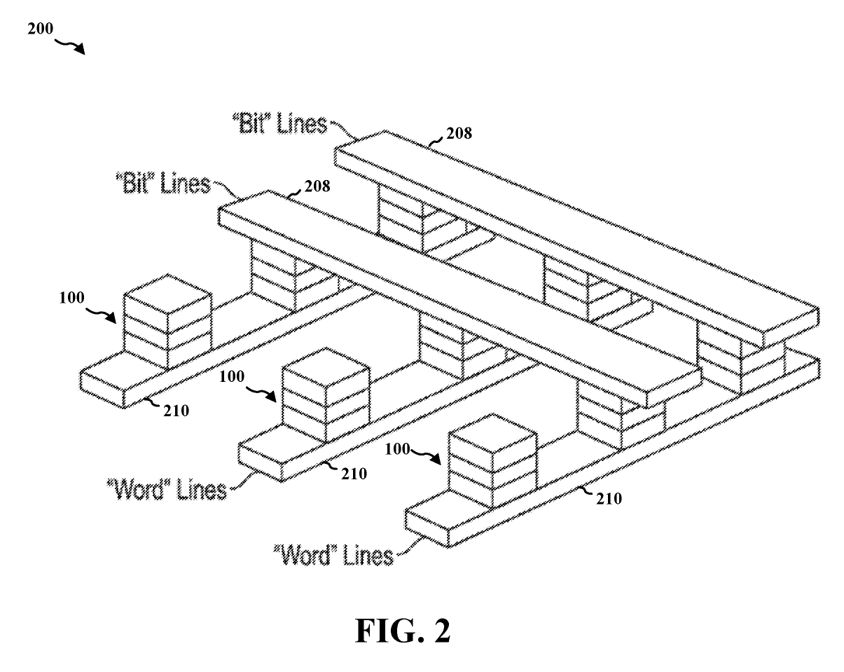

FIG. 2 illustrates an example MRAM with an array of MTJ memory cells 100 connected to word lines 210 and bit lines 208 in an example cross-point architecture.

Spin orbit torques (SOT) can originate from spin hall or Rashba effects and may be generated by current flowing through a wire of a material with a large spin-orbit coupling. SOT avoids the need for large currents to be passed through a tunnel barrier of an MTJ during a write operation. This improves the endurance of the memory. Greater switching efficiency may be possible, e.g., by finding proper materials/geometry. Improved switching efficiency would lead to improved write error rates. With SOT, the write current flows through interconnects and enables a larger current to be available, because the interconnect selectors are larger than the bit selectors. An SOT cross-point architecture may also eliminate a need for individual select transistors for each cell, although a selector for read operations will still be needed.

Torque strength is proportional to the intrinsic spin orbit coupling strength of the material used and the current density flowing through the interconnect wire. PMA MTJ bits are more desirable as they allow for higher bit densities due to higher thermal stability, however deterministic switching of these bits with the spin hall effect requires the generation of an external magnetic field, which is difficult.

Using SOT, MTJ bits can be written without passing any current across the tunnel barriers, effectively leading to infinite endurance for MRAM. Additionally, this spin hall effect method could eventually be more efficient than STT, e.g., based on material choices, making the write process more efficient. Spin hall switching could also eliminate the need for select transistors in a cross-point architecture, allowing for greater memory densities.

PMA MTJs are more desirable than in-plane magnetized MTJs for memory, because they allow higher data storage density. However, switching PMA layers requires both a current through the spin hall material and a magnetic field bias along the direction of current flow in order to reliably switch the PMA MTJ between different states. It is desirable to design a spin hall effect (SHE) MRAM cell that can switch PMA layers without needing such an external magnetic field.

An antiferromagnet (AFM) exchange coupled to the PMA free layer may be used to provide an effective in plane field on the ferromagnet free layer. Coupled with another spin hall layer (such as Ta or Pt) to generate spin current, this may allow switching of the PMA layer without an external magnetic field. For example, switching has been shown in hall crosses patterned out of a simple material stack such as MgO/AFM/FM/Ta or Pt. A memory cell cannot be implemented using this type of material stack, because a memory cell requires MTJs with high magnetoresistance (MR), which is achieved by positioning the oxide tunnel barrier directly on the free layer. Therefore, the free layer cannot be sandwiched between an AFM layer and a spin hall layer, because the free layer needs to be directly adjacent to the oxide tunnel barrier layer.

Aspects presented herein provide an MRAM cell configured to use the spin hall effect to write by switching a state of the MTJ bits without requiring an external magnetic field. Aspects presented herein overcome the need to generate an external magnetic field by utilizing an antiferromagnetic layer both as the interconnect, e.g., spin hall material, to generate spin current and as a mechanism to pin the free layer and to provide an exchange bias field to assist with switching PMA bits. The use of this type of interconnect removes the need for the free layer to be sandwiched between an AFM and a spin hall layer which enables the oxide tunnel barrier to be provided on the other side of the free layer. Previous MRAM cells used a nonmagnetic material such as Ta, Pt, or W for the interconnect in contact with the free layer. The MRAM cell presented herein may use an interconnect composed of an antiferromagnetic material such as chromium (Cr), nickel oxide (NiO), iron oxide (FeO), iridium manganese (IrMn), iron manganese (FeMn), or platinum manganese (PtMn), among others.

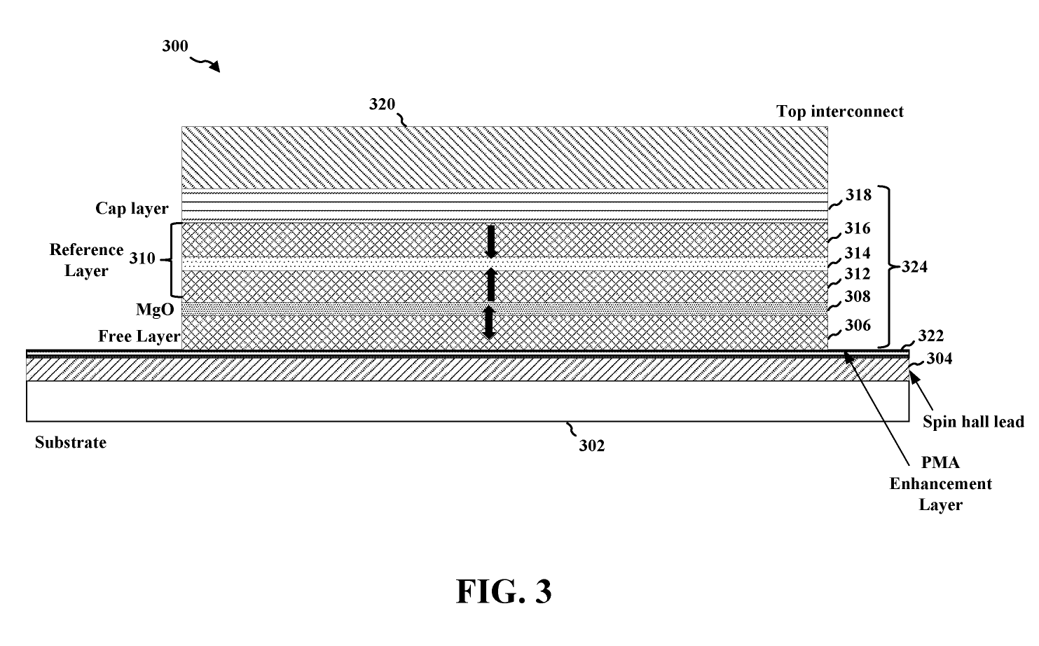

FIG. 3 illustrates an example MRAM cell 300 having an MTJ 324 and interconnect 304 positioned between the MTJ 324 and substrate 302. The substrate may be formed of semiconductor grade silicon, oxidized silicon, or aluminum-titanium-carbide, among other suitable substrate materials. The MTJ stack 324 includes free layer 306, which may be a PMA free layer. The interconnect 304 may be configured to generate a spin current as well as a magnetic field effect that is used to affect the magnetic moment of the free layer 306. The interconnect 304 may be a spin hall lead. The interconnect 304 may comprise an antiferromagnetic material, e.g., at least one of Cr, NiO, FeO, IrMn, FeMn, and PtMn.

The interconnect 304 may comprise an antiferromagnetic material exchange coupled to the free layer 306 and configured to generate a spin current. The MTJ stack may be a PMA MTJ having PMA a free layer and a tunnel barrier 308 deposited directly on a side of the free layer 306. The interconnect 304 may be positioned on an opposite side of the free layer 306 and configured to generate a spin current.

The spin current generated by the interconnect 304 may apply a spin orbit torque to the free layer to affect a magnetic moment of the free layer. For example the spin torque may be used to switch the state of the cell, e.g., between the two states illustrated in FIGS. 1A and 1B.

The MTJ stack may include reference layer 310 and a tunnel barrier layer 308 between the reference layer 310 and the free layer 306. The free layer 304 and the reference layer 310 may each comprise a ferromagnetic material. The tunnel barrier layer 308 may comprise MgO, AlOx, or another suitable oxide tunnel barrier material. The ferromagnetic reference layer 310 may have a fixed magnetization perpendicular to the plane of the reference layer, e.g., as illustrated in FIGS. 1A and 1B. The ferromagnetic free layer 304 may have a magnetization that is capable of being switched between parallel and antiparallel to the reference layer's 310 magnetization. FIG. 1A shows an example when the free layer 304 has a magnetization that is parallel to the reference layer's magnetization state. This state of the cell may provide a low resistance state and may designate a “0,” for example. FIG. 1B shows an example when the free layer 304 has a magnetization that is antiparallel to the reference layer's magnetization state. This state of the cell may provide a higher resistance state and may designate a “1,” for example.

The reference layer 310 may comprise multiple layers, e.g., ferromagnetic layers 312 and 316 antiferromagnetically coupled through a thin Ru layer 314. Ferromagnetic layers 312 and 316 may each be comprised of some combination of Co/Pt, Co/Pd, or Co/Ni superlattices, CoFeB, and/or PMA inducing alloys such as FePt. The TMR of the resultant MTJ will be dependent on the relative orientation (P or AP) between the free layer 306 and the ferromagnetic layer 312 adjacent to the tunnel barrier layer 308.

The MRAM 300 may include a second interconnect 320 on an opposite side of the MTJ stack 324 from the interconnect 304 and perpendicular to interconnect 304, e.g., similar to line 208 extending perpendicular to line 210 in FIG. 2. Therefore, FIG. 3 illustrates a cross section of top interconnect 320 in the direction in which it extends. The second interconnect may comprises a conductive material, such as Cu, Al, etc.

The MRAM may include a cap layer 318 between the MTJ stack 324 and the second interconnect 320.

Antiferromagnets such as Cr, NiO, and IrMn may have spin hall angles (efficiencies) not far from more traditional spin hall materials such as Pt, Ta, and W. Thus, aspects provided herein avoid the use of two separate materials, e.g., (1) Ta or Pt or W on one side of a ferromagnet used as spin hall layer and (2) an AFM on the other side to exchange bias the ferromagnet. Instead, the AFM interconnect 304 sits on one side of the ferromagnetic free layer 306. Thus, the oxide tunnel barrier 308 can be grown on the opposite side of the free layer 306 in order to maintain high MR and signal, which is crucial for memory operation.

Additionally, the MRAM cell presented herein may include a thin interfacial layer as an enhancement layer 322 positioned between an antiferromagnetic interconnect layer 304 and the ferromagnetic free layer 306 of the MTJ stack 324. The interfacial layer may have a thickness of less than 2 nm and may also be referred to as a film. The interfacial layer may be composed of any of hafnium (Hf), iridium (Ir), tantalum (Ta), palladium (Pd), and platinum (Pt), etc. In one example, the interfacial layer may comprise Hf. The interfacial layer may help with generating the perpendicular magnetic anisotropy and improve or enhance the interfacial transparency for spins generated in the antiferromagnetic interconnect to travel into the free layer. Thus, the interfacial layer/enhancement layer may be referred to as a perpendicular magnetic anisotropy enhancement layer.

Prior to patterning of the bit/interconnect, the interfacial layer may be annealed in field parallel to the plane along a direction that the spin hall interconnect will be patterned so as to provide some small exchange field in the plane along the interconnect to assist with spin hall switching of the PMA free layer.

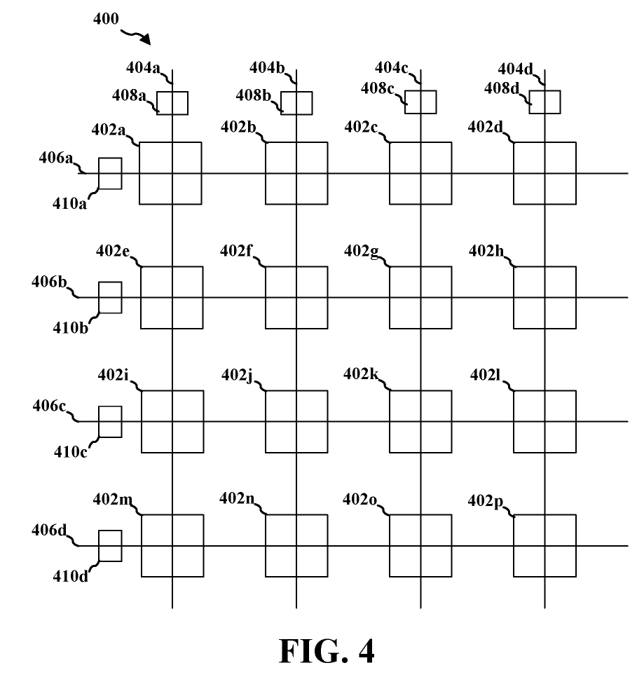

Although only a single cell is illustrated in FIG. 3, these aspects may be applied to a cell array, e.g., similar to the array illustrated in FIG. 2, such that the array includes a plurality of bit elements each configured to store at least one bit. FIG. 4 illustrates an example MRAM array 400. FIG. 4 is not drawn to scale and is merely an illustration of the concept of an MRAM array. Each of the bit elements or cells 402a-p may be configured with an MTJ stack having aspects illustrated in connection with FIG. 3.

Interconnects 404a-d may be formed in lines. Interconnects 406a-d may be formed as lines crossing interconnects 404a-d. An MTJ stack may be formed at the positions where the various interconnects cross each other. The MTJ stack may be positioned between the interconnects 404a-d and 406a-d, as illustrated in FIGS. 2 and 3 so that the interconnects are coupled to the plurality of bit elements 402a-p. For example, interconnects 404a-d may correspond to interconnect 304 in FIG. 3 and interconnects 406a-d may correspond to interconnect 320 in FIG. 3. A transistor or more than one transistor may be formed at a periphery of the MRAM cell array and may be configured to supply a current to the plurality of bit elements via the corresponding interconnect. For example, transistors 408a-d are provided for corresponding interconnects 404a-d, and transistors 410a-d are provided for corresponding interconnects 406a-d. A single transistor may be provided for each interconnect, or multiple transistors may be provided for each interconnect. However, aspects presented herein remove the need to have a transistor provided at each bit element.

The interconnect, e.g., 404a, may be configured to generate a spin current and a magnetic field effect that is used to affect the magnetic moment of the free layer of each of the plurality of bit elements, e.g., 402a, 402e, 402i, 402m, to which it is coupled. The spin current may be configured to apply a spin orbit torque to the free layer to affect a magnetic moment of each of the plurality of bit elements 402a, 402e, 402i, 402m.

Aspects of MRAM cell 300 may be used in both cross-point and 1R 2T type architectures. 1R 2T is a memory cell array having 1 resistive memory and 2 transistors per memory cell.

The need for a transistor corresponding to each individual bit can be overcome by using two write mechanisms, e.g., one applied via interconnect 404a and another applied via interconnect 406a in the example array of FIG. 4. Both write mechanism may be applied at a reduced strength, such as at half the normal amount of energy. The only bit that would be affected by the write mechanisms will be at the point that the two interconnects cross. The other bits will only receive partial energy, which will not switch the state of the bits. For example, when a signal is applied to interconnect 404a, that will be applied to each of the bit elements 402a, 402e, 402i, 402m, to which it is coupled. Similarly, a signal applied to interconnect 406a will be applied to bit elements 402a-d. If a reduced amount of energy is applied to both interconnect 404a and 406a, then the combined energy received at bit element 402a may be enough to switch the state of bit element 402a. However, bit elements 402b-e, 402i, and 402m receive only the partial energy from one of the interconnects and may not be switched.

The MTJ stack, such as the example illustrated in FIG. 3, may be grown with an antiferromagnetic interconnect layer, a thin PMA enhancement layer, a free layer, an oxide tunnel barrier layer, a reference layer, and a cap layer. After the MTJ stack has been layered, an exchange bias may be set by annealing the MTJ stack with a magnetic field in the plane of the field pointing in the direction that the antiferromagnetic interconnect will be patterned. The antiferromagnetic interconnect may also be referred to as a bottom interconnect. The antiferromagnetic interconnect may be a spin hall lead. The interconnect may be patterned under a plurality of MTJ stacks in an array, e.g., as illustrated in connection with FIG. 2. The MTJ stack can then be patterned to create the bottom antiferromagnetic interconnect and isolated MTJ bits or cells. Then, top leads/interconnects can be deposited and patterned on an opposite side of the MTJ stack from the bottom interconnect. Thus, prior to bit or cell fabrication, the MTJ film stack may be annealed in a field parallel to the plane along which the direction that the spin hall lead will be patterned, thereby providing a small exchange field in plane to assist with the spin hall switching of the free layer for each of the bits/cells. FIG. 2 illustrates a set of bottom interconnects, referred to as word lines 210, and top interconnects, referred to as bit lines 208. In FIG. 2, an array of MTJ stacks 100 are provided between the two interconnects 208, 210.

The various aspects of this disclosure are provided to enable one of ordinary skill in the art to practice the concepts disclosed herein. Various modifications to example aspects presented throughout this disclosure will be readily apparent to those skilled in the art, and the example aspects disclosed herein may be extended to other applications. Thus, the claims are not intended to be limited to the various aspects of this disclosure, but are to be accorded the full scope consistent with the language of the claims. All structural and functional equivalents to the various elements of the MRAM cell and MRAM cell array described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f), or applicable analogous statute or rule of law, unless the element is expressly recited using the phrase “means for” or, in the case of a method claim, the element is recited using the phrase “step for.”

1. A magnetoresistive random access memory (MRAM) cell, comprising:
a magnetic tunnel junction (MTJ) stack having a free layer; and
an interconnect configured to generate a spin current and a magnetic field effect that is used to affect the magnetic moment of the free layer.

2. The MRAM cell of claim 1, wherein the interconnect comprises a Spin Hall lead.

3. The MRAM cell of claim 1, wherein the interconnect comprises an antiferromagnetic material.

4. The MRAM cell of claim 3, wherein the antiferromagnetic material includes at least one of chromium (Cr), nickel oxide (NiO), iron oxide (FeO), iridium manganese (IrMn), iron manganese (FeMn), or platinum manganese (PtMn).

5. The MRAM cell of claim 1, further comprising:
an enhancement layer located between the interconnect and the MTJ stack, wherein the enhancement layer comprises at least one of hafnium (Hf), iridium (Ir), tantalum (Ta), palladium (Pd), and platinum (Pt).

6. The MRAM cell of claim 5, wherein the enhancement layer comprises a perpendicular magnetic anisotropy enhancement layer having a thickness of less than 2 nm.

7. The MRAM cell of claim 1, wherein the MTJ stack further comprises:
a perpendicular magnetic anisotropy reference layer; and
a tunnel barrier layer between the reference layer and the free layer,
wherein each of the free layer and the reference layer comprises a ferromagnetic material.

8. A magnetoresistive random access memory (MRAM) cell array, comprising:
a plurality of bit elements each configured to store at least one bit;
an interconnect coupled to the plurality of bit elements; and
at least one transistor formed at a periphery of the MRAM cell array and configured to supply a current to the plurality of bit elements via the interconnect,
wherein the interconnect is configured to generate a spin current and a magnetic field effect that is used to affect the magnetic moment of the free layer of each of the plurality of bit elements.

9. A magnetoresistive random access memory (MRAM) cell, comprising:
a magnetic tunnel junction (MTJ) stack having a free layer; and
an antiferromagnetic material exchange coupled to the free layer and configured to generate a spin current.

10. The MRAM cell of claim 9, wherein the antiferromagnetic material comprises a Spin Hall lead.

11. The MRAM cell of claim 9, wherein the antiferromagnetic material includes at least one of chromium (Cr), nickel oxide (NiO), iron oxide (FeO), iridium manganese (IrMn), iron manganese (FeMn), or platinum manganese (PtMn).

12. The MRAM cell of claim 9, further comprising:
an enhancement layer located between the antiferromagnetic material and the MTJ stack, wherein the enhancement layer comprises at least one of hafnium (Hf), iridium (Ir), tantalum (Ta), palladium (Pd), and platinum (Pt).

13. The MRAM cell of claim 12, wherein the enhancement layer comprises a perpendicular magnetic anisotropy enhancement layer having a thickness of less than 2 nm.

14. The MRAM cell of claim 9, wherein the MTJ stack further comprises:
a perpendicular magnetic anisotropy reference layer; and
a tunnel barrier layer between the reference layer and the free layer,
wherein each of the free layer and the reference layer comprises a ferromagnetic material.

15. A magnetoresistive random access memory (MRAM) cell, comprising:
a magnetic tunnel junction (MTJ) stack having a free layer with perpendicular magnetic anisotropy and a tunnel barrier deposited directly on a side of the free layer; and
an interconnect positioned on an opposite side of the free layer and configured to generate a spin current.

16. The MRAM cell of claim 15, wherein the interconnect comprises an antiferromagnetic material Spin Hall lead.

17. The MRAM cell of claim 16, wherein the antiferromagnetic material includes at least one of chromium (Cr), nickel oxide (NiO), iron oxide (FeO), iridium manganese (IrMn), iron manganese (FeMn), or platinum manganese (PtMn).

18. The MRAM cell of claim 15, further comprising:
an enhancement layer located between the interconnect and the MTJ stack, wherein the enhancement layer comprises at least one of hafnium (Hf), iridium (Ir), tantalum (Ta), palladium (Pd), and platinum (Pt).

19. The MRAM cell of claim 18, wherein the enhancement layer comprises a perpendicular magnetic anisotropy enhancement layer having a thickness of less than 2 nm.

20. The MRAM cell of claim 15, wherein the MTJ stack further comprises:
a perpendicular magnetic anisotropy reference layer on the opposite side of the tunnel barrier from the free layer, wherein each of the free layer and the reference layer comprises a ferromagnetic material.
